(19) United States
(12) Patent Application Publication
(10) Pub. No.: US 2025/0100130 A1
(43) Pub. Date: Mar. 27, 2025

(54) BONDING MACHINE BOND HEAD HAVING SIX DEGREES OF FREEDOM

(71) Applicant: ASMPT Singapore Pte. Ltd., Singapore (SG)

(72) Inventors: Kuok Hang MAK, Hong Kong (CN); Ajit Shriman GAUNEKAR, Singapore (SG); Tsz Kit YU, Hong Kong (CN); Ka Shing KWAN, Singapore (SG)

(21) Appl. No.: 18/373,373

(22) Filed: Sep. 27, 2023

(51) Int. Cl. B25J 9/04; B25J 9/00; B25J 11/00

(52) U.S. Cl. CPC B25J 9/041; B25J 9/0096; B25J 11/005

(57) ABSTRACT

A bond head having a bonding tool for bonding an electronic component includes a rotary motion mechanism and a linear positioning mechanism coupled to the rotary motion mechanism. The rotary motion mechanism is operative to rotate the bonding tool for adjusting an angular orientation of the electronic component held by the bonding tool. The rotary motion mechanism includes a rotary assembly operative to rotate the bonding tool about a first rotary axis and a flexural rotary table operative to rotate the bonding tool about respective second and third rotary axes, the first, second and third rotary axes being orthogonal to one another. The linear positioning mechanism is operative to drive the bonding tool to move parallel to the first rotary axis as well as a first plane that is parallel to a second plane on which the second and third rotary axes are located to adjust the position of the electronic component.

### FIELD OF THE INVENTION

The invention relates to a bond head of a bonding apparatus or machine which has six degrees of freedom (DOF), and in particular to such a bond head incorporating a tip-tilt mechanism to enable the six DOF, a bonding machine including the said bond head and a bonding method utilized by the said bond head.

### BACKGROUND

Adhesive bonding is a key packaging process in the manufacturing of electronic devices and this technique has been widely employed for electrically connecting electronic components by the use of adhesives. The quality of the adhesive bonding plays a crucial role in the thermal performance, reliability and lifespan of electronic devices. For instance, the thickness, evenness and coverage of an adhesive layer must be well controlled during a bonding process to ensure the performance of the electronic devices.

The quality of such bonding using adhesives may be affected by variations in the geometric features that occur on mating surfaces between an electronic component and a base member to be joined or connected. Having tight tolerances on dimensions and geometric features of the electronic component has typically been implemented to reduce any excessive variations. However, it is not a cost-effective approach, and sometimes it is even not possible to find technical solutions to achieve such tight tolerances. In particular, the miniaturization of electronics requires much higher accuracy and precision to fulfill the tight tolerances required for electronic assemblies. This makes the bonding process more challenging and as a result, improved processes and equipment are needed to cope with excessive variations of geometric features and imperfections of the electronic components used in the electronic assemblies.

In the prior art, various bonding machines are specially designed to automate the process of adhesive bonding to ensure the quality thereof. In these bonding machines, conventional bond heads are designed to adjust the orientation and position of the electronic component in three orthogonal linear motion axes and one rotary axis. However, these conventional four-axis bond heads do not have enough degrees of freedom to adjust the orientation of the electronic component in a three-dimensional space before the electronic component is placed to ensure that it is bonded accurately onto the base member. In essence, two degrees of freedom are absent from the conventional four-axis bond heads, namely in the tip and tilt directions respectively. The lack of the ability to adjust a bond head in the tip and tilt directions may lead to poor coplanarity between the two mating surfaces. As a result, a load applied by the bond head during the bonding process may not be distributed uniformly to the adhesive sandwiched between the mating surfaces, such that the adhesive does not evenly cover the designated bonding area. Consequently, partial coverage and uneven thickness of the adhesive layer may occur in the bonded electronic assembly and eventually this would significantly reduce heat dissipation, reliability, and lifespan of the electronic devices.

It would therefore be beneficial to provide greater degrees of freedom for adjusting the orientation of the electronic component before the electronic component is bonded.

### SUMMARY OF THE INVENTION

It is thus an object of this invention to seek to provide a more effective and cost-efficient solution for adjusting the orientation of the electronic component in a three-dimensional space so as to compensate for the variations of geometric features of the electronic components that may affect the parallelism between the mating surfaces. This solution can dramatically lessen the dependence of assembly accuracy on the geometric tolerances of the electronic components.

According to a first aspect of the invention, there is provided a bond head for a bonding machine having a bonding tool for bonding an electronic component. The bond head includes a rotary motion mechanism operative to rotate the bonding tool for adjusting an angular orientation of the electronic component held by the bonding tool. The rotary motion mechanism comprises a rotary assembly operative to rotate the bonding tool about a first rotary axis and a flexural rotary table operative to rotate the bonding tool about respective second and third rotary axes, the first, second and third rotary axes being orthogonal to one another; and a linear positioning mechanism coupled to the rotary motion mechanism and operative to drive the bonding tool to move parallel to the first rotary axis as well as along a first plane that is parallel to a second plane on which the second and third rotary axes are located. The linear positioning mechanism may be used for adjusting the position of the electronic component held by the bonding tool along three axes of a Cartesian coordinate system.

With such a bond head, the orientation of the electronic component held by the bonding tool of the bond head may be adjusted about three rotary axes and the position of the electronic component may be adjusted in three linear motion axes. As such, the angular orientation and position of the electronic component may be effectively adjusted in all six degrees of freedom. In other words, the bond head is enabled to move through a three-dimensional space to adjust the orientation and position of the electronic component before bonding the electronic component to a base member. Further, the flexural rotary table is designed to frictionlessly guide the adjustment of the angular orientation of the electronic component in the tip and tilt directions. This helps improve the accuracy and repeatability of the motion performance and the lifespan of the bond head.

The rotary motion mechanism may be directly coupled to the bonding tool. In other words, the rotary assembly or the flexural rotary table may be directly coupled to the bonding tool. Alternatively, the linear positioning mechanism may be directly coupled to the bonding tool. The linear positioning mechanism may include three sequentially connected/coupled linear motion assemblies. Any of the three linear motion assemblies may be directly coupled to the bonding tool. In one preferred embodiment, the bond head is designed to be in a serial mechanical configuration where one motion assembly is installed onto another motion assembly, and all linear motions and rotary motions along or about different axes are independent of one another.

In one embodiment, the linear positioning mechanism may include a first linear motion assembly, a second linear motion assembly disposed on the first linear motion assembly and a third linear motion assembly disposed on the second linear motion assembly, wherein the first, second and third motion assemblies drive the bonding tool to move along three orthogonal axes respectively in a Cartesian coordinate system.

The flexural rotary table may include a first rotatable stage, a second rotatable stage and a base plate, a first flexural joint coupled between the first rotatable stage and the base plate to enable the first rotatable stage to be rotatable about the second rotary axis, and a second flexural joint coupled between the first and second rotatable stages to enable the second rotatable stage to rotate about the third rotary axis. As the first and second flexural joints form a deformable rotary guiding system without any moving parts for the tip and tilt movements, the absence of friction and stick-slip motion from the guiding system significantly improves the repeatability and precision of the tip and tilt movements of the bond head.

The first flexural joint may include a first pair of flexural hinges that are arranged on opposite sides of the first rotatable stage between the first rotatable stage and the base plate such that the two flexural hinges are operable to flex about the second rotary axis synchronously. The second flexural joint may include a second pair of flexural hinges that are arranged on opposite sides of the second rotatable stage between the first and second rotatable stages such that the two flexural hinges are operable to flex about the third rotary axis synchronously. Each flexural hinge may include two crossed-leaf springs. The flexural hinges are not subject to wear and do not require lubricants so they are particularly suitable for use in cleanrooms whereas lubrication is required for the conventional guiding mechanisms involving moving parts, such as bearings.

Preferably, a second rotary axis passing through the first pair of flexural hinges may be perpendicular to the third rotary axis passing through the second pair of flexural hinges. As such, the second and third rotary axes are perpendicular to each other and lay on a plane on which they intersect. The point of intersection of these two axes can be regarded as the center of the rotation of the flexural rotary table. This design can prevent unwanted translations from occurring on the rotary axis of a rotatable stage due to the rotational movement of the other rotatable stage, such as, unwanted translations of the third rotary axis of the second rotatable stage due to the rotational movement of the first rotatable stage.

The linear positioning mechanism may be configured to drive the bonding tool to move along the first plane in a first linear motion axis and a second linear motion axis, the first and second linear motion axes being arranged at an angle of 45 degrees with respect to the second and third rotary axes respectively. This structural arrangement helps evenly balance the weight of the flexural rotary table on three linear motion assemblies of the linear positioning mechanism about a central plane that is parallel to a plane on which the first rotary axis and an axis that is 45 degrees away from the second rotary axis of the bond head are located, thereby improving the dynamical performance of the mechanical structure of the bond head.

The rotary motion mechanism may further include a first driving system and/or a second driving system. The first driving system is installed on the base plate of the flexural rotary table and coupled to a first arm protruding from the first rotatable stage by a resilient member so as to provide a force to the first arm to rotate the first rotatable stage about the first flexural joint, i.e., rotate the first rotatable stage about the second rotary axis when guided by the first flexural joint. The second driving system is installed on the first rotatable stage and coupled to a second arm protruding from the second rotatable stage by a resilient member so as to provide a force to the second arm to rotate the second rotatable stage about the second flexural joint. The resilient member may include a pair of preloaded extension springs.

In one embodiment, at least one of the first and second driving systems may include a cam driving assembly that includes an eccentric cam and a rotary motor coupled to the first and/or second arm. The rotary motion mechanism may further include at least one rotary encoder integrated with the rotary motor for measuring an angular displacement of the rotary motor, which is then used to determine a corresponding linear displacement of the eccentric cam. Specifically, the first driving system may include a first cam driving assembly that includes a first eccentric cam and a first rotary motor coupled to the first arm, and the second driving system may include a second cam driving assembly that includes a second eccentric cam and a second rotary motor coupled to the second arm.

The flexural rotary table may include a hollow section sized for accommodating and mounting the rotary assembly and for coupling the bonding tool to the rotary assembly. The arrangement of the hollow section in the flexural rotary table makes the bond head compact in size and facilitates locating the rotary assembly closer to the rotation center of the flexural rotary table. Thus, any unwanted translations that may arise from the tip and tilt movements can be minimized.

According to a second aspect of the invention, there is provided a bonding machine comprising a bond head having a bonding tool for bonding an electronic component. The bond head includes a rotary motion mechanism operative to rotate the bonding tool for adjusting an angular orientation of the electronic component held by the bonding tool, wherein the rotary motion mechanism comprises a rotary assembly operative to rotate the bonding tool about a first rotary axis and a flexural rotary table operative to rotate the bonding tool about respective second and third rotary axes, the first, second and third rotary axes being orthogonal to one another; and a linear positioning mechanism coupled to the rotary motion mechanism and operative to drive the bonding tool to move parallel to the first rotary axis as well as along a first plane that is parallel to a second plane on which the second and third rotary axes are located.

According to a third aspect of the invention, there is provided a method for manufacturing an electronic package including an electronic component which is bonded onto a surface of the electronic package using a bonding tool of a bond head, the method includes: rotating the bonding tool with a rotary motion mechanism about a first rotary axis for adjusting an angular orientation of the electronic component held by the bonding tool; rotating the bonding tool with a flexural rotary table about at least one of second and third rotary axes, the first rotary axis being orthogonal to the second and third rotary axes; moving the bonding tool with a linear positioning mechanism coupled to the rotary motion mechanism parallel to the first rotary axis and a first plane parallel to a second plane on which the second and third rotary axes are located; and bonding the electronic component onto the surface with the bonding tool.

These and other features, aspects, and advantages will become better understood with regard to the description section, appended claims, and accompanying drawings.

### BRIEF DESCRIPTION OF THE DRAWINGS

Embodiments of the present invention will now be described, by way of example only, with reference to the accompanying drawings, in which:

FIG. 1 is a schematic perspective view of a bond head having six DOF according to one embodiment of the invention;

FIG. 2A shows a perspective view of a flexural rotary table of a rotary motion mechanism of the bond head as shown in FIG. 1;

FIG. 2B and FIG. 2C respectively show side views of the flexural rotary table as shown in FIG. 2A looking along the x-axis and y-axis respectively indicated in FIG. 1;

FIG. 3A shows a flexural cross-strip hinge of the first and second flexural joints of the flexural rotary table as shown in FIG. 2A;

FIG. 3B is a perspective view of the flexural rotary table in FIG. 2A showing the flexural cross-strip hinges of the first and second flexural joints of the flexural rotary table;

FIG. 4 shows a plan view of a bond head according to one embodiment of the invention.

In the drawings, like parts are denoted by like reference numerals.

### DETAILED DESCRIPTION

Before discussing embodiments in detail, an overview will first be provided. Embodiments of the invention provide a bond head of a bonding machine having six DOF for bonding an electronic component to a base member. The bond head is capable of rotating a bonding tool carried by it about three orthogonal rotary axes to adjust the angular orientation of the electronic component held by the bonding tool and for moving the bonding tool along three orthogonal axes of a Cartesian coordinate system to adjust the position of the electronic component. The said bond head is able to move and rotate the electronic component in a three-dimensional space to accurately adjust the position and angular orientations of the electronic component. Furthermore, a flexure-based mechanism is designed and used to provide frictionless and repeatable guiding when conducting tip and tilt movements of the bond head, i.e., rotation of the bond tool about two of the three orthogonal rotary axes.

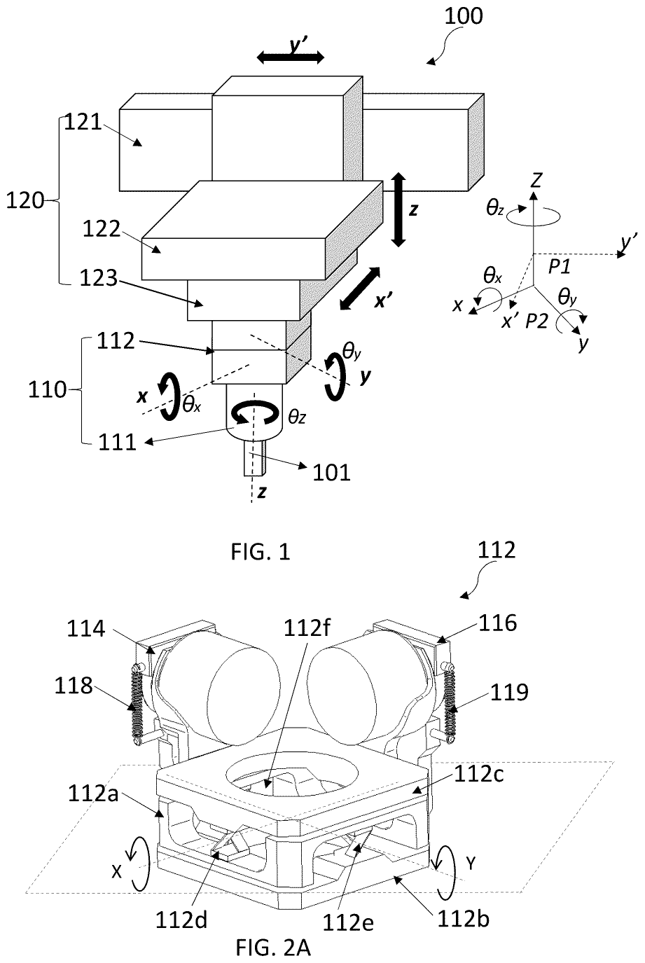

FIG. 1 is a schematic perspective view of a bond head 100 according to one embodiment of the invention. Referring to FIG. 1, a bonding tool 101 is coupled to the bond head 100 for bonding an electronic component to a base member (not shown in figures). The bond head 100 includes a linear positioning mechanism 120 and a rotary motion mechanism 110 coupled to the linear positioning mechanism 120. Correspondingly, the bonding tool 101 is directly coupled to the rotary motion mechanism 110.

The rotary motion mechanism 110 is operative to rotate the bonding tool 101 about the orthogonal x, y, and z rotary axes for adjusting the angular orientation (θx, θy, θz) of the electronic component held by the bonding tool 101. In this embodiment, the rotary motion mechanism 110 includes a rotary assembly 111 and a flexural rotary table 112 coupled to the rotary assembly 111. The bonding tool 101 is directly installed on the rotary assembly 111. The rotary assembly 111 is configured and operative to rotate the bonding tool 101 about the z-axis (the first rotary axis) so as to adjust the angular orientation θz of the electronic component held by the bonding tool 101. The flexural rotary table 112 is a key substructure of the bond head 100, which is configured and operative to also rotate the bonding tool 101 respectively about the x-axis and y-axis (the second and third rotary axes) so as to adjust the angular orientation θy and θz of the electronic component held by the bonding tool 101. The flexural rotary table 112 is also referred to as a flexural tip-tilt stage for guiding the tip and tilt movements (i.e., rotations about the x-axis and the y-axis) of the bond tool 101 held by the bond head 100.

The linear positioning mechanism 120 is operative to drive the bonding tool 101 to move along three orthogonal linear motion axes (x′, y′, z) for linearly adjusting the position of the electronic component held by the bonding tool 101. Referring to FIG. 1, the x′-y′ plane P1 on which the linear motion axes x′-axis and y′-axis are located is parallel to the x-y plane P2 on which the rotary x-axis and y-axis are located. Also, the x′-axis and y′-axis are arranged at an oblique angle with respect to the x-axis and y-axis respectively. Preferably, the oblique angle in this embodiment is 45 degrees.

The linear positioning mechanism 120 may include a first linear motion assembly 121, a second linear motion assembly 122 attached to the first linear motion assembly 121 and a third linear motion assembly 123 attached to the second linear motion assembly 122. The flexural rotary table 122 is directly attached to the third linear motion assembly 123. The first linear motion assembly 121 is configured to drive the bonding tool 101 to move along the y′-axis direction for adjusting the position of the electronic component held by the bonding tool 101 in the y′-axis direction. The second linear motion assembly 122 is configured to drive the bonding tool 101 to move along the z-axis direction for adjusting the position of the electronic component in the z-axis direction. The third linear motion assembly 123 is configured to drive the bonding tool 101 to move along the x′-axis direction for adjusting the position of the electronic component in the x′-axis direction.

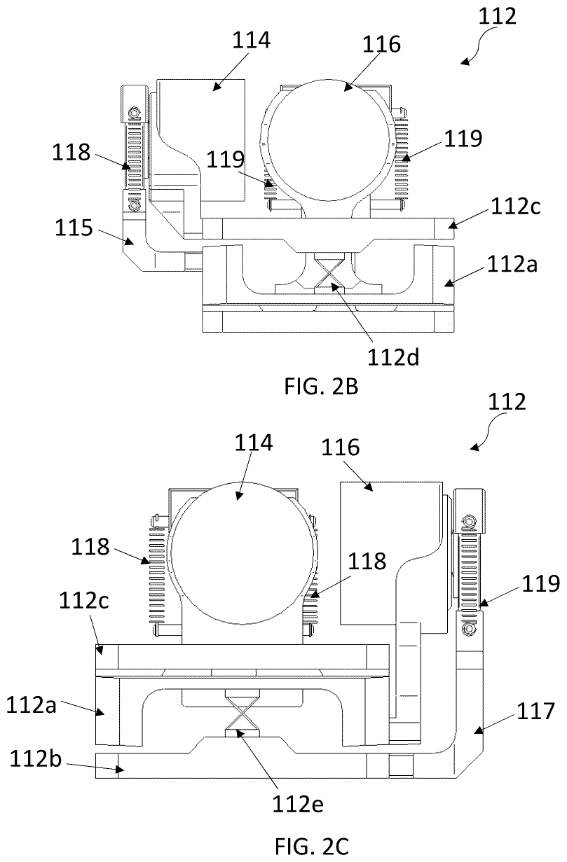

FIG. 2A shows a perspective view of the flexural rotary table 112 of the rotary motion mechanism 110. FIGS. 2B and 2C respectively show side views of the flexural rotary table 112 along the x-axis and y-axis respectively. Referring to FIG. 2A, the flexural rotary table 112 includes a first rotatable stage 112a, a second rotatable stage 112b and a base plate 112c. The flexural rotary table 112 also includes a first flexural joint 112d coupled between the first rotatable stage 112a and the base plate 112c to enable the first rotatable stage 112a to be rotatable about the x-axis and a second flexural joint 112e coupled between the first and second rotatable stages 112a, 112b to enable the second rotatable stage 112b to be rotatable about the y-axis. The first and second flexural joints 112d, 112e are designed to be employed in the flexural rotary table 112 to provide frictionless and repeatable guidance to the tip and tilt movements respectively of the first rotatable stage 112a.

The rotary motion mechanism 110 further includes a first cam driving system 114 and a second cam driving system 116 for automatically activating and controlling the tip and tilt movements of the bond tool 101 respectively. Each driving system includes an eccentric cam and a rotary motor which are designed to convert rotary motions into linear motions. Referring to FIG. 2B and FIG. 2C, the first cam driving system 114 is installed on the base plate 112c of the flexural rotary table 112 and coupled to the first rotatable stage 112a by a resilient member 118 so as to provide a force to rotate the first rotatable stage 112a about the first flexural joint 112d. In this embodiment, the first cam driving system 14 may be coupled to the first rotatable stage 112a via a first arm (tip arm) 115 protruding from the first rotatable state 112a. The first arm 115 may be integrally formed with the first rotatable stage 112a and protruding therefrom or attached to the first rotatable stage 112a by any appropriate attachment means. The resilient member 118 may include a pair of preloaded extension springs. Specifically, the first cam driving system 114 may be coupled to the first arm 115 through the resilient member 118 such that the force from the first cam driving system 114 can be transferred to the first arm 115 in order to generate a moment to rotate the first rotatable stage 112a through the guidance provided by the first flexural joint 112d coupled between the first rotatable stage 112a and the base plate 112c. In this embodiment, the first cam driving system 114 includes a first eccentric cam and a first rotary motor coupled to the first arm 115. Further, a first rotary encoder may be integrated with the first rotary motor for measuring an angular displacement of the first rotary motor, which is then used to determine a corresponding linear displacement of the first eccentric cam. A displacement sensor, such as a linear encoder, may also be employed to measure the linear displacement of the first cam driving system 114. The measured linear displacement of the first eccentric cam of the first cam driving system 114 is used to calculate the angular movement of the first rotatable stage 112a. It would also be possible to use a sensor to directly measure the angular displacement of the first rotatable stage 112a relative to the base plate 112c.

The second cam driving system 116 is installed on the first rotatable stage 112a and coupled to the second rotatable stage 112b by a resilient member 119 so as to provide a force to rotate the second rotatable stage 112b about the second flexural joint 112e. In this embodiment, the second cam driving system 116 may be coupled to the second rotatable stage 112b via a second arm (tilt arm) 117 protruding from the second rotatable state 112b. The second arm 117 may be integrally formed with the second rotatable stage 112b and protruding therefrom or attached to the second rotatable stage 112b by any appropriate attachment means. The resilient member 119 may include a pair of preloaded extension springs. Specifically, the second cam driving system 116 may be coupled to the first arm 117 through the resilient member 119 such that the force from the second cam driving system 116 can be transferred to the second arm 117 in order to generate a moment to rotate the second rotatable stage 112b through the guidance provided by the second flexural joint 112e coupled between the first rotatable stage 112a and the second rotatable state 112b. In this embodiment, the second cam driving system 116 includes a second eccentric cam and a second rotary motor coupled to the second arm 117. Further, a second rotary encoder may be integrated with the second rotary motor for measuring an angular displacement of the second rotary motor, which is then used to determine a corresponding linear displacement of the second eccentric cam. Similar to the first rotatable stage 112a, different types of encoders may be used to measure the linear displacement of the second eccentric cam of the second scam driving system 116 or the angular displacement of the second rotatable stage 112b.

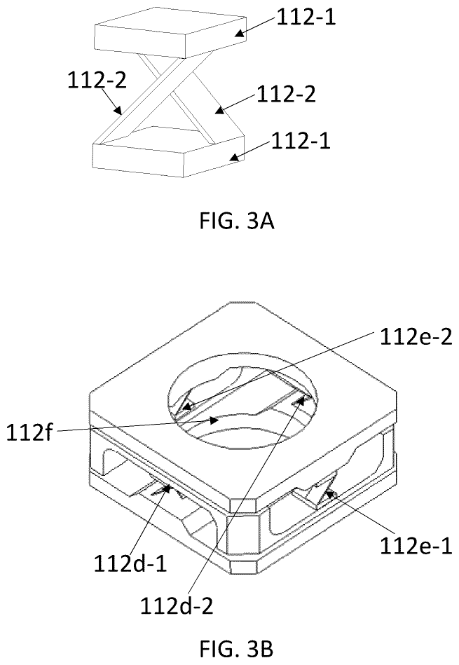

Each of the first and second flexural joints 112d and 112e may include a pair of cross-strip hinges. FIG. 3A shows a flexural cross-strip hinge of the first and second flexural joints 112d, 112e. Each flexural hinge may include two crossed-leaf springs. In this embodiment, each flexural hinge may include a cross-strip hinge formed by connecting two substantially parallel rigid plates 112-1 with a pair of leaf springs 112-2 that cross each other at a certain angle, typically at 90 degrees.

FIG. 3B is a perspective view of the flexural rotary table 112 showing the flexural cross-strip hinges of the first and second flexural joints 112d and 112e. As shown in FIG. 3B, the first flexural joint 112d includes a pair of flexural cross-strip hinges 112d-1 and 112d-2 that are arranged on opposite sides of the first rotatable stage 112a between the first rotatable stage 112a and the base plate 112c. The pair of flexural cross-strip hinges 112d-1 and 112d-2 are arranged such that the two flexural cross-strip hinges 112d-1 and 112d-2 are operable to flex about the x-axis synchronously. The second flexural joint 112e includes a pair of flexural cross-strip hinges 112e-1 and 112e-2 that are arranged on opposite sides of the second rotatable stage 112b between the first and second rotatable stages 112a, 112b. The pair of flexural cross-strip hinges 112e-1 and 112e-2 are arranged such that the two flexural cross-strip hinges 112e-1 and 112e-2 are operable to flex about the y-axis synchronously. In this embodiment, the two pairs of flexural cross-strip hinges 112d-1, 112d-2, 112e-1 and 112e-2 are arranged such that a line passing through the pair of flexural cross-strip hinges 112d-1 and 112d-2, i.e., the x-axis (second rotary axis) passing therethrough as shown in FIG. 2A, is perpendicular to a line passing through the pair of flexural cross-strip hinges 112e-1 and 112e-2, i.e., the y-axis (third rotary axis) passing therethrough as shown in FIG. 2A. Also, the flexural cross-strip hinges of the first and second flexural joints 112d and 112e are arranged to make sure that the x-axis and the y-axis are located on the same plane.

It should be noted that the flexural cross-strip hinges are provided for illustration purposes only and are not intended to limit the scope of the invention. Other types of flexural hinges may also be used in this invention.

As shown in FIG. 2A and FIG. 3B, the flexural rotary table 112 may be designed to include a hollow section 112f sized for accommodating and mounting the rotary assembly 111 such that the bonding tool 101 can be coupled to the rotary assembly 111. This hollow section configured for accommodating the rotary assembly 111 helps minimize the size of the bond head and can also facilitate installing the rotary assembly 111 closer to a center of rotation of the flexural rotary table 112 so as to minimize unwanted translations of the bond head 100 due to the aforesaid tip and tilt movements.

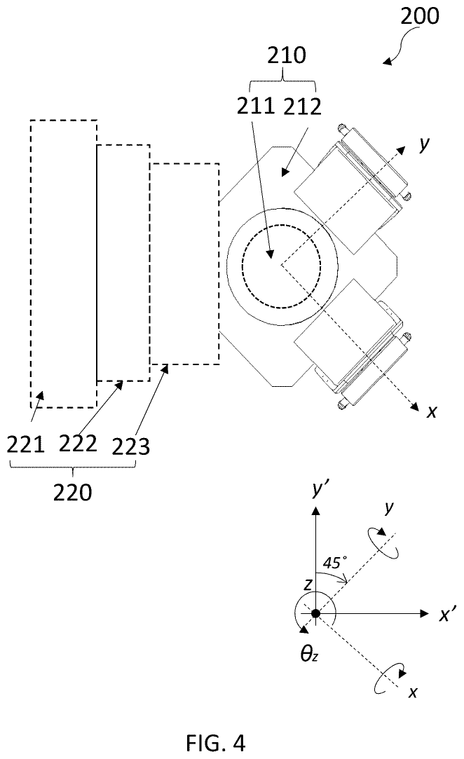

FIG. 4 shows a plan view of a bond head 200 according to one embodiment of the invention. The bond head 200 includes a rotary motion mechanism 210 and a linear positioning mechanism 220 coupled to the rotary motion mechanism 210. The rotary motion mechanism 210 includes a rotary assembly 211 and a flexural rotary table 212. The rotary assembly 211 may be coupled to the flexural rotary table 212 and arranged to pass through a hollow section of the flexural rotary table 212 such that a bonding tool may be installed on one end of the rotary assembly 211. The linear positioning mechanism 220 includes an x′-axis linear motion assembly 221, a z-axis linear motion assembly 222 disposed on the x′-axis linear motion assembly 221 and a y′-axis linear motion assembly 223 disposed on the z-axis linear motion assembly 222. The x′-axis linear motion assembly 221 is configured for driving the bond tool installed on the rotary assembly 211 to move along the x′-axis direction. The z-axis linear motion assembly 222 is configured for driving the bond tool installed on the rotary assembly 211 to move along the z-axis direction. The y′-axis linear motion assembly 223 is configured for driving the bond tool installed on the rotary assembly 211 to move along the y′-axis direction. The flexural rotary table 212 is directly coupled to the y-axis linear motion assembly 223. The flexural rotary table 212 is operative to rotate a bonding tool installed on the rotary assembly 211 about a tilt axis x and a tip axis y respectively. The tilt axis x is arranged at an angle of 45 degrees with respect to the x′-axis and the tip axis y is arranged at an angle of 45 degrees with respect to the y′-axis.

When the bond head 100, 200 is used to pick up or to place an electronic component during a bonding process, a method for manufacturing an electronic package including an electronic component which has been bonded onto a surface of the electronic package using the bond head 100, 200 includes the following steps:
Step 1: the bonding tool 101 of the bond head 100, 200 is rotated by the rotary motion mechanism 110, 210 for adjusting an angular orientation of the electronic component held by the bonding tool 101.

Specifically, in this step 1, the bonding tool 101 may be rotated by a rotary assembly 111, 211 of the rotary motion mechanism 110, 210 about the z-axis to adjust an angular orientation θz of the electronic component, and/or the bonding tool 101 may be rotated by a flexural rotary table 112, 212 of the rotary motion mechanism 110, 210 about at least one of the x-axis and y-axis to adjust the angular orientation θx, θy of the electronic component held by the bonding tool 101.
Step 2: the bonding tool 101 is moved by a linear positioning mechanism 120, 220 coupled to the rotary motion mechanism 110, 120 along at least one of the x′-axis, y′-axis and z-axis to adjust the position of the electronic component held by the bonding tool 101.

It should be noted that the sequence of step 1 and step 2 may be changed in other embodiments. That is to say, the position of the electronic component held by the bonding tool 101 may be first adjusted using the linear positioning mechanism 120, 220, followed by the step of adjusting the angular orientation of the electronic component held by the bonding tool 101 using the rotary motion mechanism 110, 210. Alternatively, the electronic component may also be adjusted by the linear positioning mechanism 120, 220 and the rotary motion mechanism 110, 210 simultaneously.
Step 3: the electronic component is bonded onto the surface of the electronic package using the bonding tool 101.

Various modifications may be made to the above-described embodiments. The sequential order of the mechanical arrangement of the rotary motion mechanism 110, 210 and the linear positioning mechanism 120, 220 may be different in other embodiments. For example, the flexural rotary table 112, 222 may be disposed on the rotary assembly 111, 211 and the bond tool 101 may be directly installed on the flexural rotary table 112, 222; the sequential order of the x-axis, y-axis and z-axis linear motion assemblies may be different; or the linear positioning mechanism 120, 220 may be installed on the rotary motion mechanisms 110 and 210, and the bonding tool 101 may be directly coupled to the linear positioning mechanism 120, 220. The first and second cam driving systems 114 and 116 may also be replaced with other types of driving systems as long as the driving systems can be used for driving the tip and tilt movements of the flexural rotary table 112, 212. The flexural cross-strip hinges of the first and second flexural joints 112d and 112e may be replaced by other types of flexural hinges or flexural structures as long as they are operative to guide the tilt and tip movements of the first and second rotatable stages 112a and 112b.

The invention described herein is susceptible to variations, modifications and/or additions other than those specifically described and it is to be understood that the invention includes all such variations, modifications and/or additions which fall within the spirit and scope of the above description.

1. A bond head for a bonding machine having a bonding tool for bonding an electronic component, the bond head comprising:
a rotary motion mechanism operative to rotate the bonding tool for adjusting an angular orientation of the electronic component held by the bonding tool, wherein the rotary motion mechanism comprises a rotary assembly and a flexural rotary table coupled to each other,
the rotary assembly being operative to rotate the bonding tool about a first rotary axis and the flexural rotary table being operative to rotate the bonding tool about respective second and third rotary axes, the first, second and third rotary axes being orthogonal to one another; and
a linear positioning mechanism coupled to the rotary motion mechanism and operative to drive the bonding tool to move parallel to the first rotary axis as well as along a first plane that is parallel to a second plane on which the second and third rotary axes are located.

2. The bond head according to claim 1, wherein the rotary assembly or the flexural rotary table is directly coupled to the bonding tool.

3. The bond head according to claim 1, wherein the flexural rotary table comprises a first rotatable stage, a second rotatable stage, and a base plate, a first flexural joint coupled between the first rotatable stage and the base plate to enable the first rotatable stage to be rotatable about the second rotary axis, and a second flexural joint coupled between the first and second rotatable stages to enable the second rotatable stage to rotate about the third rotary axis.

4. The bond head according to claim 3, wherein the first flexural joint includes a first pair of flexural hinges that are arranged on opposite sides of the first rotatable stage between the first rotatable stage and the base plate such that the two flexural hinges are operable to flex about the second rotary axis synchronously.

5. The bond head according to claim 4, wherein the second flexural joint includes a second pair of flexural hinges that are arranged on opposite sides of the second rotatable stage between the first and second rotatable stages such that the two flexural hinges are operable to flex about the third rotary axis synchronously.

6. The bond head according to claim 5, wherein each flexural hinge comprises two crossed leaf springs.

7. The bond head according to claim 5, wherein a line passing through the first pair of flexural hinges is perpendicular to a line passing through the second pair of flexural hinges.

8. The bond head according to claim 7, wherein the linear positioning mechanism is configured to drive the bonding tool to move along the first plane in a first linear motion axis and a second linear motion axis, the first and second linear motion axes being arranged at an angle of 45 degrees with respect to the second and third rotary axes respectively.

9. The bond head according to claim 3, wherein the rotary motion mechanism further comprises a first driving system that is installed on the base plate of the flexural rotary table and coupled to a first arm protruding from the first rotatable stage by a resilient member so as to provide a force to the first arm to rotate the first rotatable stage about the first flexural joint.

10. The bond head according to claim 9, wherein the rotary motion mechanism further comprises a second driving system that is installed on the first rotatable stage and coupled to a second arm protruding from the second rotatable stage by a resilient member so as to provide a force to the second arm to rotate the second rotatable stage about the second flexural joint.

11. The bond head according to claim 10, wherein the resilient member includes a pair of preloaded extension springs.

12. The bond head according to claim 10, wherein at least one of the first and second driving systems comprises a cam driving assembly that includes an eccentric cam and a rotary motor coupled to the first and/or second arm.

13. The bond head according to claim 12, wherein the rotary motion mechanism further comprises a rotary encoder integrated with the rotary motor for measuring an angular displacement of the rotary motor, which is then used to determine a corresponding linear displacement of the eccentric cam.

14. The bond head according to claim 3, wherein the flexural rotary table includes a hollow section sized for accommodating and mounting the rotary assembly and for coupling the bonding tool to the rotary motion mechanism.

15. The bond head according to claim 1, wherein the linear positioning mechanism includes a first linear motion assembly, a second linear motion assembly disposed on the first linear motion assembly and a third linear motion assembly disposed on the second linear motion assembly, wherein the first, second and third motion assemblies drive the bonding tool to move along three orthogonal axes respectively in a Cartesian coordinate system.

16. A bonding machine comprising a bond head having a bonding tool for bonding an electronic component, the bond head comprising:
a rotary motion mechanism operative to rotate the bonding tool for adjusting an angular orientation of the electronic component held by the bonding tool, wherein the rotary motion mechanism comprises a rotary assembly operative to rotate the bonding tool about a first rotary axis and a flexural rotary table operative to rotate the bonding tool about respective second and third rotary axes, the first rotary axis being orthogonal to the second and third rotary axes; and
a linear positioning mechanism coupled to the rotary motion mechanism and operative to drive the bonding tool to move parallel to the first rotary axis as well as along a first plane that is parallel to a second plane on which the second and third rotary axes are located.

17. A method for manufacturing an electronic package including an electronic component which is bonded onto a surface of the electronic package using a bonding tool, the method comprising:
rotating the bonding tool with a rotary motion mechanism about a first rotary axis for adjusting an angular orientation of the electronic component held by the bonding tool;
rotating the bonding tool with a flexural rotary table about at least one of second and third rotary axes, the first rotary axis being orthogonal to the second and third rotary axes;
moving the bonding tool with a linear positioning mechanism coupled to the rotary motion mechanism parallel to the first rotary axis and a first plane parallel to a second plane on which the second and third rotary axes are located; and
bonding the electronic component onto the surface with the bonding tool.
